(19) United States
(12) Patent Application Publication
(10) Pub. No.: US 2022/0064791 A1
(43) Pub. Date: Mar. 3, 2022

(54) WAFER CARRIER AND METAL ORGANIC CHEMICAL VAPOR DEPOSITION APPARATUS

(71) Applicant: PlayNitride Display Co., Ltd., MiaoLi County (TW)

(72) Inventors: Shen-Jie Wang, MiaoLi County (TW); Yen-Lin Lai, MiaoLi County (TW); Jyun-De Wu, MiaoLi County (TW); Chien-Chih Yen, MiaoLi County (TW)

(73) Assignee: PlayNitride Display Co., Ltd., MiaoLi County (TW)

(21) Appl. No.: 17/523,914

(22) Filed: Nov. 11, 2021

Related U.S. Application Data
(63) Continuation-in-part of application No. 16/191,455, filed on Nov. 15, 2018.

(30) Foreign Application Priority Data
Nov. 16, 2017 (TW) 106139651

(51) Int. Cl. C23C 16/458

(52) U.S. Cl. CPC C23C 16/4584

(57) ABSTRACT

A wafer carrier including a rotation axis, a center flat region, a wafer distributing region and a plurality of wafer accommodating grooves is provided. The rotation axis passes through a center of the center flat region and a surface of the center flat region is a flat surface. The wafer distributing region surrounds the center flat region. The plurality of wafer accommodating grooves are disposed in the wafer distributing region and arranged in a single virtual loop. A diameter of each of the wafer accommodating grooves is D, and a radius of the center flat region is larger than 0.5D. A wafer carrier and a metal organic chemical vapor deposition apparatus using any of the above two wafer carriers are further provided.

### CROSS-REFERENCE TO RELATED APPLICATION

This application is a continuation-in-part application of and claims the priority benefit of U.S. application Ser. No. 16/191,455, filed on Nov. 15, 2018, now pending, which claims the priority benefit of Taiwan application serial no. 106139651, filed on Nov. 16, 2017. The entirety of each of the above-mentioned patent applications is hereby incorporated by reference herein and made a part of this specification.

### BACKGROUND OF THE INVENTION

### Field of the Invention

The invention relates to a carrier and an apparatus, and more particularly, to a wafer carrier and a metal organic chemical vapor deposition apparatus.

### Description of Related Art

Metal organic chemical vapor deposition (MOCVD) is a method currently used for epitaxial processing on wafers. During the MOCVD process, the wafers are placed on a wafer carrier. Process parameters such as temperature, gas pressure, and gas flow rate within the chamber are controlled to grow the epitaxial film layers. Based on production considerations, the number of the wafers placed on the wafer carrier are preferably as many as possible. However, if the distance between adjacent wafers is too close, the wavelength uniformity of the wafers is readily affected.

### SUMMARY OF THE INVENTION

The invention provides a wafer carrier that improves wavelength uniformity.

The invention provides a metal organic chemical vapor deposition apparatus using the above wafer carrier.

A wafer carrier of the invention used to carry a plurality of wafers includes a rotation axis, a center flat region, a wafer distributing region and a plurality of wafer accommodating grooves. The rotation axis passes through a center of the center flat region and a surface of the center flat region is a flat surface. The wafer distributing region surrounds the center flat region. The plurality of wafer accommodating grooves are disposed in the wafer distributing region and arranged in a single virtual loop. A diameter of each of the wafer accommodating grooves is D, and a radius of the center flat region is larger than 0.5D.

A metal organic chemical vapor deposition apparatus of the invention includes a chamber, a rotating device, a gas supply and the aforementioned wafer carrier. The rotating device is located in the chamber. The gas supply is connected to the chamber. The wafer carrier is located in the chamber and disposed on the rotating device. The gas supply injects a gas from a top of the chamber into the chamber, and the wafer carrier rotates around the rotation axis.

In an embodiment of the invention, no wafer accommodating groove exists out of the single virtual loop.

In an embodiment of the invention, the plurality of wafer accommodating grooves are disposed out of the center flat region.

In an embodiment of the invention, a spacing between each wafer accommodating groove and the rotation axis is the same.

In an embodiment of the invention, a center of each wafer accommodating groove has an identical distance from the rotation axis on a radial direction of the center flat region.

In an embodiment of the invention, a thickness of the center flat region is greater than a depth of each wafer accommodating groove.

In an embodiment of the invention, the single virtual loop is a circle.

In an embodiment of the invention, a minimum distance between an edge of each wafer accommodating groove and an edge of the wafer carrier is in a range from 10 mm to 15 mm.

In an embodiment of the invention, a revolution speed of the wafer carrier is A1 rpm, a minimum distance between an edge of each wafer accommodating groove and an edge of the wafer carrier is A2 mm, and a ratio of A1 to A2 is in a range from 50 to 100.

Based on the above, in the wafer carrier of an embodiment of the invention, the airflow interference caused by the distance between the adjacent wafers being too short is alleviated by the design in which the wafer accommodating grooves are not disposed in the center flat region. The wafer accommodating grooves are disposed in the wafer distributing region and arranged in a single virtual loop. A diameter of each of the wafer accommodating grooves is D, and a radius of the center flat region is larger than 0.5D. Therefore, the wafer carrier of an embodiment of the invention may improve wavelength uniformity. Moreover, a wafer having good epitaxial quality may be manufactured by the metal organic chemical vapor deposition apparatus using the above wafer carrier.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a wafer carrier according to the first embodiment of the invention.

FIG. 1B is a cross-section of section line A-A′ in FIG. 1A.

FIG. 2 to FIG. 4 are respectively top views of wafer carriers according to the second embodiment to the fourth embodiment of the invention.

FIG. 5 is a schematic of a metal organic chemical vapor deposition apparatus according to an embodiment of the invention.

### DESCRIPTION OF THE EMBODIMENTS

The technical contents, features, and effects of the invention will be apparent from the following detailed description of each embodiment of the drawings. In the following embodiments, wordings used to indicate direction, such as “up,” “down,” “front,” “back,” “left,” and “right”, merely refer to directions in the drawings. Therefore, the directional terms are used to illustrate and are not intended to limit the invention. Moreover, in any of the embodiments below, the same or similar reference numerals are used for the same or similar devices.

The wafer carrier in any of the following embodiments may be applied to a metal organic chemical vapor deposition apparatus. In the process of the metal organic chemical vapor deposition, a wafer carrier is used to carry a plurality of wafers to be processed. The wafer carrier may be produced from any material that is resistant to processing temperature. For example, the material of the wafer carrier may be graphite or graphite-coated material, but is not limited thereto.

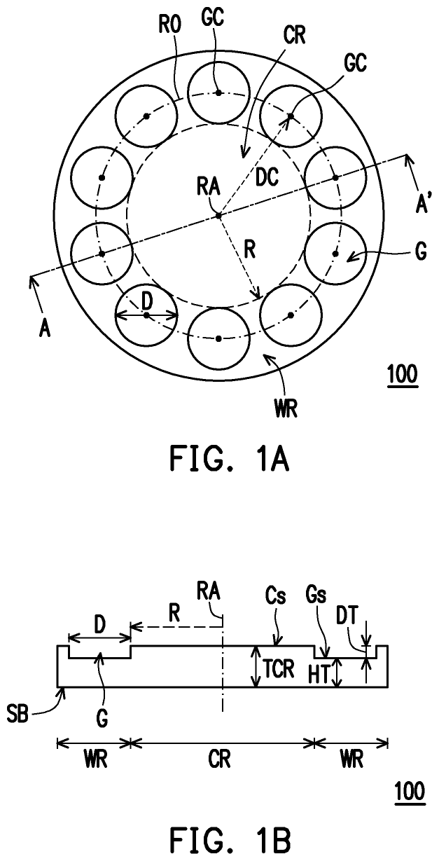

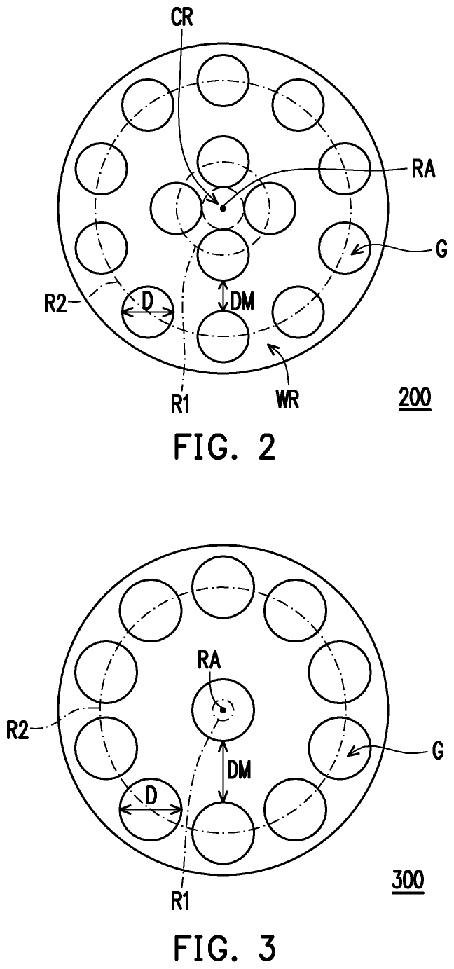

FIG. 1A is a top view of a wafer carrier according to the first embodiment of the invention. FIG. 1B is a cross-section of section line A-A′ in FIG. 1A. Referring to FIG. 1A and FIG. 1B, a wafer carrier 100 of the first embodiment of the invention includes a bottom surface SB, a rotation axis RA, a center flat region CR, a wafer distributing region WR, and a plurality of wafer accommodating grooves G arranged in a virtual loop R0. The virtual loop R0 is a single and unique virtual loop on the wafer carrier 100, and the virtual loop R0 is a circle. No wafer accommodating groove exists out of the virtual loop R0. A spacing between each wafer accommodating groove G and the rotation axis RA is the same. Each center GC of the plurality of wafer accommodating grooves G in the virtual loop R0 has an identical distance DC from the rotation axis RA on a radial direction of the center flat region CR. None of the plurality of wafer accommodating grooves G is disposed in the center flat region CR. That is, the plurality of wafer accommodating grooves G are disposed out of the center flat region CR. The rotation axis RA passes through the center of the center flat region CR (the shape of the center flat region CR of the present embodiment is, for example, a circle, and the center of the center flat region CR is the center point of the center flat region CR). The wafer distributing region WR surrounds the center flat region CR. The plurality of wafer accommodating grooves G are disposed in the wafer distributing region WR. The diameter of each of the wafer accommodation grooves G is D, and a radius R of the center flat region CR is larger than 0.5D. A thickness TCR of the wafer carrier 100 in the center flat region CR is greater than a depth DT of each of the wafer accommodating grooves G in the wafer distributing region WR. Here, the radius of the center flat region CR is defined as the shortest distance from the rotation axis RA to the edge of the wafer accommodating grooves G. More specifically, in the wafer carrier 100 of the first embodiment, there are no wafer accommodating grooves G, nor high and low patterns, within the range of the radius R from the rotation axis RA (that is, in the range of the center flat region CR), such that a surface Cs of the center flat region CR is a flat surface. The wafer distributing region WR has concave wafer accommodating grooves G, that is, the distance (the thickness TCR) of the wafer carrier 100 from the surface Cs of the center flat region CR to the bottom surface SB is greater than a distance HT from a bottom surface Gs of the wafer accommodating grooves G to the bottom surface SB.

More specifically, the plurality of wafer accommodating grooves G are located on a surface of the wafer carrier 100 opposite to the bottom surface SB of the wafer carrier 100, that is, each of the plurality of wafer accommodating grooves G is a groove extended toward the bottom surface SB of the wafer carrier 100 to house a wafer. The surface Cs of the center flat region CR and the bottom surface Gs of the wafer accommodating grooves G are both opposite to the bottom surface SB and substantially parallel to the bottom surface SB. However, the plurality of wafer accommodating grooves G do not penetrate through the wafer carrier 100. That is to say, the height difference of the center flat region CR is much less than the height difference of the wafer distributing region WR. For example, the height difference of the surface Cs of the center flat region CR is in the range of ODT to 0.1DT, and the surface Cs is a continuous flat surface, but is not limited thereto. In the embodiment, the surface Cs of the center flat region CR is a flat surface, that is, the height difference of the surface Cs is 0, and the height difference of the wafer distributing region WR is the depth DT of the wafer accommodating grooves G.

During the processing, a plurality of wafers are respectively disposed in the plurality of wafer accommodating grooves G, and the wafer carrier 100 rotates around the rotation axis RA, such that the plurality of wafers revolve around the rotation axis RA, thereby providing a uniform gas environment for epitaxy process. Each of the wafer accommodating grooves G may be formed by a patterning process, and therefore the bottom surface Gs or the side surface (not labeled) of the wafer accommodating grooves G may also be roughened by a process, such that the surface roughness of the bottom surface Gs or the side surface is greater than the surface roughness of the surface Cs of the center flat region CR. In other words, the surface roughness of the center flat region CR is better than the surface roughness of the wafer accommodating groove G. As a result, the plurality of wafers are more firmly fixed in the plurality of wafer accommodating grooves G during processing, thereby avoiding the separation of the plurality of wafers from the plurality of wafer accommodating grooves G during the rotation of the wafer carrier 100.

The airflow interference caused by the distance between the adjacent wafers being too short may be avoided by the design in which the wafer accommodating grooves G are not disposed in the center flat region CR. Therefore, the uniformity of the film deposited on the wafers are improved.

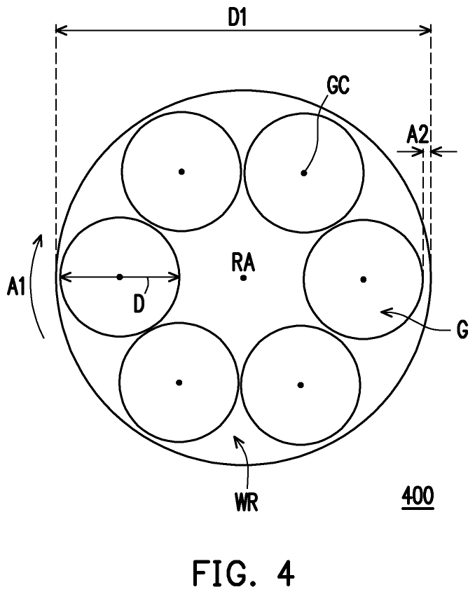

FIG. 2 and FIG. 3 are respectively top views of wafer carriers according to the second embodiment and the third embodiment of the invention.

Referring to FIG. 2 and FIG. 3, a wafer carrier 200 of the second embodiment and a wafer carrier 300 of the third embodiment of the invention also include a rotation axis RA and a plurality of wafer accommodating grooves G. The plurality of wafer accommodating grooves G are spaced apart and arranged on a first virtual loop R1 and a second virtual loop R2. The first virtual loop R1 and the second virtual loop R2 are defined according to the arrangement of the plurality of wafer accommodating grooves G, and a physical mark does not need to be formed on the wafer carrier (such as the wafer carrier 200 and the wafer carrier 300). More specifically, the plurality of wafer accommodating grooves G are arranged into at least one ring array centered on the rotation axis RA, and one of the plurality of wafer accommodating grooves G may be (but not necessarily) disposed at the center of the wafer carrier. The virtual loops pass through the center of the plurality of wafer accommodating grooves G of the same ring array. In the case where only one of the wafer accommodating grooves G is disposed at the center of the wafer carrier, the first virtual loop R1 is substantially overlapped with the rotation axis RA. However, to clearly indicate the first virtual loop R1, the first virtual loop R1 in FIG. 3 is depicted as surrounding the rotation axis RA.

In the second embodiment shown in FIG. 2, the plurality of wafer accommodating grooves G are arranged into two ring arrays. The two ring arrays share a central axis (i.e., the rotation axis RA) and are arranged outwardly from the center of the wafer carrier 200. The two ring arrays respectively define the first virtual loop R1 and the second virtual loop R2. In the third embodiment shown in FIG. 3, in addition to the wafer accommodating groove G located at the center of the wafer carrier 300, the remaining plurality of wafer accommodating grooves G are arranged into one ring array. The wafer accommodating groove G located at the center of the wafer carrier 300 defines the first virtual loop R1, and the ring array defines the second virtual loop R2.

In the second embodiment and the third embodiment, the diameter of each of the wafer accommodating grooves G is D, and a shortest distance DM between the edges of any two adjacent wafer accommodating grooves G respectively located on the first virtual loop R1 and the second virtual loop R2 is greater than 0.1D and less than 5D. The shortest distance DM is preferably 0.2D to 3D. By controlling the shortest distance DM of two adjacent wafer accommodating grooves G on two adjacent virtual loops, the airflow interference caused by the distance between two adjacent wafers on two adjacent virtual loops being too short may be avoided, and the problem of low production caused by the distance between two adjacent wafers on two adjacent virtual loops being too long can be avoided. Therefore, the wafer carrier 200 and the wafer carrier 300 not only may improve the uniformity of the film deposited onto the wafers, but may also facilitate production capacity.

It should be noted that although the second embodiment and the third embodiment are both illustrated by two virtual loops, the number of virtual loops may be changed according to requirements (the wafer carrier may also include two or more virtual loops), and the number of virtual loops should not be limited by the examples shown in FIG. 2 and FIG. 3.

FIG. 4 is the top view of a wafer carrier according to the fourth embodiment of the invention.

Referring to FIG. 4, a wafer carrier 400 of the fourth embodiment of the invention includes a plurality of wafer accommodating grooves G disposed in the wafer distributing region WR. A ratio of the diameter D1 of the wafer carrier 400 to the diameter D of each wafer accommodation groove G is about 3.245. In the present embodiment, the diameter D1 of the wafer carrier 400 is about 490 mm, and the diameter D of each wafer accommodation groove G is about 151 mm. However, the invention is not limited thereto.

A revolution speed of the wafer carrier 400 is A1 rpm, and the minimum distance between the edge of each wafer accommodating groove G and the edge of the wafer carrier 400 is A2 mm. In the disclosure, a ratio of A1 to A2 is in a range from 50 to 100. In the present embodiment, the revolution speed of the wafer carrier 400 is in a range of 500-1000 rpm, and the minimum distance A2 is in a range from 10 mm to 15 mm. However, the invention is not limited thereto.

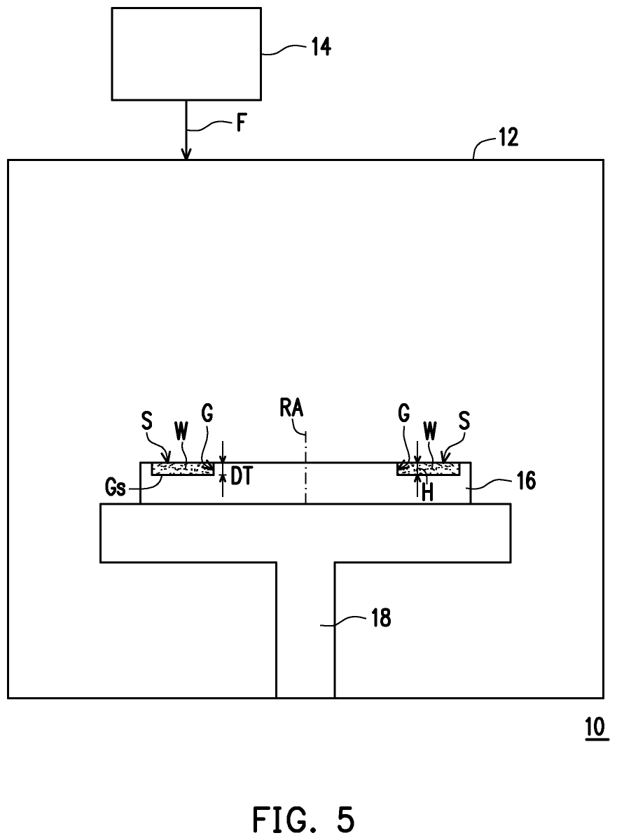

FIG. 5 is a schematic of a metal organic chemical vapor deposition apparatus according to an embodiment of the invention.

Referring to FIG. 5, a metal organic chemical vapor deposition (MOCVD) apparatus 10 of an embodiment of the invention includes a chamber 12, a gas supply 14, and a wafer carrier 16. The gas supply 14 is connected to the chamber 12, and the gas supply 14 provides the gas required for the process. The wafer carrier 16 is disposed in the chamber 12. The wafer carrier 16 adopts the wafer carrier 100 shown in FIG. 1A and FIG. 1B, the wafer carrier 200 shown in FIG. 2, or the wafer carrier 300 shown in FIG. 3.

During the processing, a plurality of wafers W are respectively disposed in the plurality of wafer accommodating grooves G of the wafer carrier 16. The plurality of wafers W may be disk-like structures formed by sapphire, silicon carbide (SiC), silicon, GaAs, GaP, InP, GaN or other crystal substrates. The gas supply 14 injects a gas F from the top of the chamber 12 into the chamber 12. In order to prevent the gas F being presented as a nono-steady gas flow when reaching each wafer accommodating groove G of the wafer carrier 100 rotating at a high revolution speed, the radius R of the center flat region CR of the wafer carrier 100 should be large enough. Take the wafer carrier 100 for example. Since the radius R of the center flat region CR of the wafer carrier 100 is larger than 0.5D, the gas F provided by the gas supply 14 is presented as a steady gas flow when reaching each wafer accommodating groove G. To the contrary, when the radius R of the center flat region CR of the wafer carrier 100 is smaller than 0.5D, the gas F reaching each wafer accommodating groove G may not be steady. The metal organic chemical vapor deposition apparatus 10 may further include a rotating device 18, wherein a rotating shaft (not shown) of the rotating device 18 is aligned with the rotation axis RA of the wafer carrier 16, and the rotating shaft is connected to a rotational driving mechanism (not shown). The rotational driving mechanism drives the rotation of the rotating shaft to drive the wafer carrier 16 to rotate around the rotation axis RA, such that the plurality of wafers W revolve around the rotation axis RA, thereby facilitating the uniform airflow to a processing surface S of each of the plurality of wafers W in a gas environment in the chamber 12. In the embodiment, the plurality of wafers W revolve only around the rotation axis RA without rotating in the wafer accommodating grooves G. Preferably, the processing surface S of the wafers W does not protrude out of the wafer accommodating grooves G. A thickness H of the wafer W is equal or smaller than a depth DT of the wafer accommodating grooves G, more specific, the thickness H is not greater than 0.7DT, that is, 0.7 DT≤H≤DT. If the processing surface S protrudes out of the wafer accommodating grooves G, the wafers W are unstable due to the rotating centrifugal force, and if the processing surface S is too low, the uniformity of the film deposition is affected. In some embodiments of the present application, the depth DT of the wafer accommodating groove G is about 650 um, and the radius R of the center flat region CR is about 7.5 cm. In some embodiments of the present application, the depth DT of the wafer accommodating groove G is about 1400 um, and the radius R of the center flat region CR is about 7.5 cm.

In the wafer carrier 16, via the design in which the wafer accommodating grooves G are not disposed in the center flat region (such as the wafer carrier 100 shown in FIG. 1A and FIG. 1B) or by controlling the shortest distance between two adjacent wafer accommodating grooves G on two adjacent virtual loops (such as the wafer carrier 200 shown in FIG. 2 or the wafer carrier 300 shown in FIG. 3), the airflow interference caused by the distance between two adjacent wafers W being too short is alleviated. Therefore, the wafer carrier 16 may improve wavelength uniformity. The metal organic chemical vapor deposition apparatus 10 may produce a wafer having excellent epitaxial quality by using the wafer carrier 16. In an experimental example, the metal organic chemical vapor deposition apparatus 10 may reduce the average wavelength difference of a plurality of wafers by 33%, reduce the average wavelength standard deviation of the plurality of wafers by 27%, and reduce the within-wafer average wavelength standard deviation of each of the plurality of wafers by 41%.

The metal organic chemical vapor deposition apparatus 10 may further include other elements or devices depending on various needs. For example, the metal organic chemical vapor deposition apparatus 10 may further include a lifting mechanism (not shown) connected to the wafer carrier 16 to adjust the distance between the wafer carrier 16 and the air inlet. Further, the metal organic chemical vapor deposition apparatus 10 may further include an air suction device (not shown) connected to the chamber 12 to have an exhaust function. In addition, the metal organic chemical vapor deposition apparatus 10 may further include a cooling device (not shown) and a heating device (not shown) to control the temperature in the chamber 12 or the temperature of the wafer carrier 16.

Based on the above, in the wafer carrier of an embodiment of the invention, via the design in which the wafer accommodating grooves are not disposed in the center flat region or by controlling the shortest distance between two adjacent wafer accommodating grooves on two adjacent virtual loops, the airflow interference caused by the distance between the adjacent wafers being too short may be alleviated. Therefore, the wafer carrier of an embodiment of the invention may improve wavelength uniformity. Moreover, a wafer having good epitaxial quality may be manufactured by the metal organic chemical vapor deposition apparatus using the above wafer carrier.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A wafer carrier used to carry a plurality of wafers, comprising:
a rotation axis;
a center flat region, wherein the rotation axis passes through a center of the center flat region and a surface of the center flat region is a flat surface;
a wafer distributing region, surrounding the center flat region; and
a plurality of wafer accommodating grooves, disposed in the wafer distributing region and arranged in a single virtual loop,
wherein a diameter of each of the wafer accommodating grooves is D, and a radius of the center flat region is larger than 0.5D.

2. The wafer carrier of claim 1, wherein no wafer accommodating groove exists out of the single virtual loop.

3. The wafer carrier of claim 2, wherein the plurality of wafer accommodating grooves are disposed out of the center flat region.

4. The wafer carrier of claim 1, wherein a spacing between each wafer accommodating groove and the rotation axis is the same.

5. The wafer carrier of claim 1, wherein a center of each wafer accommodating groove has an identical distance from the rotation axis on a radial direction of the center flat region.

6. The wafer carrier of claim 1, wherein a thickness of the center flat region is greater than a depth of each wafer accommodating groove.

7. The wafer carrier of claim 1, wherein the single virtual loop is a circle.

8. The wafer carrier of claim 1, wherein a minimum distance between an edge of each wafer accommodating groove and an edge of the wafer carrier is in a range from 10 mm to 15 mm.

9. A metal organic chemical vapor deposition apparatus, comprising:
a chamber;
a rotating device, located in the chamber;
a gas supply, connected to the chamber; and
a wafer carrier, located in the chamber and disposed on the rotating device, the wafer carrier comprising:
a rotation axis;
a center flat region, wherein the rotation axis passes through a center of the center flat region and a surface of the center flat region is a flat surface;
a wafer distributing region, surrounding the center flat region; and
a plurality of wafer accommodating grooves, disposed in the wafer distributing region and arranged in a single virtual loop,
wherein a diameter of each of the wafer accommodating grooves is D, and a radius of the center flat region is larger than D/2,
wherein the gas supply injects a gas from a top of the chamber into the chamber, and the wafer carrier rotates around the rotation axis.

10. The metal organic chemical vapor deposition apparatus of claim 9, wherein no wafer accommodating groove exists out of the single virtual loop.

11. The metal organic chemical vapor deposition apparatus of claim 10, wherein the plurality of wafer accommodating grooves are disposed out of the center flat region.

12. The metal organic chemical vapor deposition apparatus of claim 9, wherein a spacing between each wafer accommodating groove and the rotation axis is the same.

13. The metal organic chemical vapor deposition apparatus of claim 9, wherein a center of each wafer accommodating groove has an identical distance from the rotation axis on a radial direction of the center flat region.

14. The metal organic chemical vapor deposition apparatus of claim 9, wherein a thickness of the center flat region is greater than a depth of each wafer accommodating groove.

15. The metal organic chemical vapor deposition apparatus of claim 9, wherein the single virtual loop is a circle.

16. The metal organic chemical vapor deposition apparatus of claim 9, wherein a minimum distance between an edge of each wafer accommodating groove and an edge of the wafer carrier is in a range from 10 mm to 15 mm.

17. The metal organic chemical vapor deposition apparatus of claim 9, wherein a revolution speed of the wafer carrier is A1 rpm, a minimum distance between an edge of each wafer accommodating groove and an edge of the wafer carrier is A2 mm, and a ratio of A1 to A2 is in a range from 50 to 100.
